(19) United States
(12) Patent Application Publication
(10) Pub. No.: US 2007/0080407 A1
(43) Pub. Date: Apr. 12, 2007

(54) Insulated gate bipolar transistor

(75) Inventor: Yoshinobu Kono, Niiza-shi (JP)

Correspondence Address: BACHMAN & LAPOINTE, P.C., 900 CHAPEL STREET, SUITE 1201, NEW HAVEN, CT, 06510, US

(73) Assignee: Sanken Electric Co., Ltd.

(21) Appl. No.: 11/543,626

(22) Filed: Oct. 5, 2006

(30) Foreign Application Priority Data
Oct. 6, 2005 (JP) 2005-293443

(51) Int. Cl. H01L 29/76

(52) U.S. Cl. 257/370

(57) ABSTRACT

An IGBT is provided which comprises N+ type extended region 9 sectively formed in P+ type collector region 1 to define a built-in diode in cooperation with N+ type extended region 9, an N− type base region 2 and a P− type base region 3 in semiconducting substrate 10. N− type base region 2 comprises a recombination region 21 developed between P type base region 3 and collector electrode 8 to acquire minority carriers accumulated around recombination region 21 in first base region 2 by recombination region 21 for improvement in recovery property of the diode without increasing voltage in the forward direction since recombination region 21 does not reach between and beneath adjoining second base regions 3 in N type base region 2 for current path.

### TECHNICAL FIELD

This invention relates to an insulated gate bipolar transistor, in particular, of the type having a built-in diode.

### BACKGROUND OF THE INVENTION

A typical insulated gate bipolar transistor (IGBT) comprises: a semiconducting substrate which comprises a P+ type collector region, an N type base region formed on P+ type collector region, a P type base region formed on N type base region, and N+ type emitter regions formed on an upper surface of P type base region; gate electrodes each formed in spaced relation to P type base region through an insulator; an emitter electrode formed in spaced relation to gate electrode through an insulating interlayer film and on each upper surface of P type base region and N+ type emitter region; and a collector electrode formed on a bottom surface of P+ type collector region. A part of P type base region sandwiched between N+ type emitter region and N type base region is opposite to gate electrode through gate insulation film to serve as a channel region.

Japanese Patent Disclosure No. 9-191110 discloses an IGBT which comprises a P+ type collector region, and a cathode region having an N+ type conductive region formed in an upper area of the cathode region to form a built-in diode by an anode region, N type base region and cathode region, and thereby dispense with an externally attached diode.

Diode build-in IGBT requires various recovery characteristics conformable to electric properties of electric circuits in which an IGBT is incorporated. For example, it calls for a recovery characteristics or adverse recovery characteristics with the small change rate in adverse current, a lifetime control technique has been utilized for irradiating radiation such as light ions or electron beams as a lifetime killer over a semiconducting substrate in which an IGBT and a diode are formed. Specifically, radiation is irradiated over N type regions incorporated with a diode formed therein to form crystal defects in semiconducting substrate so that the crystal defect acquires minority carriers accumulated around crystal defects in N type base region centered on recombination of electrons and positive holes to promptly extinguish minority carriers for improvement in recovery property of diode.

However, a prior art exposure technique has a process for uniformly irradiating radiation over a whole semiconducting substrate with the built-in IGBT and diode, and therefore, it disadvantageously forms crystal defects in N type base region between gate electrode and P+ type collector region to function as a main current path in IGBT. Accordingly, IGBT has an undesirably increased operating forward voltage while it acquires a soft recovery property of diode.

Meanwhile, Japanese Patent No. 2,818,959 exhibits an IGBT wherein light ion beams are irradiated in different depth of semiconducting substrate. This IGBT comprises a collector electrode, a first mask formed of aluminum mounted on the collector electrode, and a second mask formed of stainless steel with openings, wherein light ion beams are irradiated over the second mask to transmit ion beams through the openings in the second mask into N type base regions, and simultaneously transmit ion beams through the second mask into P+ type collector regions.

However, this Japanese reference discloses only a prior art for reducing tail current developed during the off-period of IGBT built in semiconducting substrate without built-in diode for improvement in switching property of IGBT.

Therefore, an object of the present invention is to provide an insulated gate bipolar transistor capable of improving recovery characteristics of built-in diode without deterioration in forward property of the transistor.

### SUMMARY OF THE INVENTION

The insulated gate bipolar transistor according to the present invention comprises: a semiconducting substrate (10) which comprises: a collector region (1) of a first conductive (P) type, a first base region (2) of a second conductive (N) type different from first conductive (P) type and formed on one main surface (1a) of collector region (1), second base regions (3) of the first conductive (P) type each formed adjacent to first base region (2), and emitter regions (4) of the second conductive (N) type each formed adjacent to corresponding second base region (3); gate electrodes (6) each formed in spaced relation to corresponding second base region (3) through an insulator (5); an emitter electrode (7) formed on one main surfaces (3a, 4a) of second base region (3) and emitter region (4); and a collector electrode (8) formed on the other main surface (1b) of collector region (1) opposite to first base region (2). An extended region (9) is selectively formed of the second conductive (N) type in collector region (1) to form a diode in cooperation with second base region (3), first base region (2) and extended region (9). First base region (2) comprises a recombination region (21) formed between each of second base regions (3) and collector electrode (8), and recombination region (21) does not reach between and beneath adjoining second base regions (3).

Recombination region (21) is provided by forming crystal defects in semiconducting substrate (10) with irradiation of radiation ray such as light ion or electron beams into semiconducting substrate (10). When a voltage is applied between emitter and collector electrodes (7, 8) with the higher potential on emitter electrode (7), the diode defined by second base region (3), first base region (2) and extended region (9) is turned on to cause electric current to flow through the diode. Then, when the diode is turned off, recombination region (21) acquires minority carriers accumulated around recombination region (21) in first base region (2) to rapidly annihilate minority carriers, thereby to shorten turning off time of the diode and improve recovery or switching property of diode. Upon turning-on of IGBT, forward electric current flows through first base region (2) between or around gate and collector electrodes (6, 8), and recombination region (21) can serve to prevent increase of voltage in the forward direction without deterioration in forward characteristics of IGBT for improvement in recovery property of the diode built-in IGBT, since recombination region (21) does not reach between and beneath adjoining second base regions (3).

Another insulated gate bipolar transistor according to the present invention comprises a semiconducting substrate (10) which comprises: a collector region (1) of a first conductive (P) type, a buffer region (11) of a second conductive (N) type different from first conductive (P) type and formed on one main surface of collector region (1), a first base region (2) of a second conductive (N) type different from first conductive (P) type and formed on one main surface (1a) of collector region (1), second base regions (3) of the first conductive (P) type each formed adjacent to first base region (2), and emitter regions (4) of the second conductive (N) type each formed adjacent to corresponding second base region (3); gate electrodes (6) each formed in spaced relation to corresponding second base region (3) through an insulator (5); an emitter electrode (7) formed on one main surfaces (3a, 4a) of second base region (3) and emitter region (4); and a collector electrode (8) formed on the other main surface (1b) of collector region (1) opposite to first base region (2). An extended region (9) is selectively formed of the second conductive (N) type in collector region (1) to form a diode in cooperation with second base region (3), first base region (2) and extended region (9). First base region (2) comprises a recombination region (21) formed between each of second base regions (3) and buffer region (11), and recombination region (21) does not reach between and beneath adjoining second base regions (3). Buffer region (11) comprises a second recombination region (23) formed between gate and collector electrodes (6, 8).

When IGBT is turned from on to off, second recombination region (23) acquires minority carriers accumulated around second recombination region (23) in buffer region (11) to rapidly annihilate minority carriers, thereby to effectively reduce tail current for improvement in switching property of IGBT.

The present invention can provide a reliable and enhanced performance insulated gate bipolar transistor without deterioration in forward characteristics for improvement in recovery characteristics of built-in diode.

### BRIEF DESCRIPTION OF THE DRAWINGS

The above-mentioned and other objects and advantages of the present invention will be apparent from the following description in connection with preferred embodiments shown in the accompanying drawings wherein:

FIG. 1 is a sectional view showing an embodiment of the insulated gate bipolar transistor according to the present invention;

FIG. 2 is a sectional view of FIG. 1 before formation of a recombination region;

FIG. 3 is a sectional view of FIG. 2 under irradiation of light ions through a mask;

FIG. 4 is a sectional view showing another embodiment of the insulated gate bipolar transistor according to the present invention;

FIG. 5 is a sectional view of first and second semiconducting substrates;

FIG. 6 is a sectional view of FIG. 5 under irradiation of light ions; and

FIG. 7 is a sectional view of FIG. 6 with an irradiation depth regulator removed.

### BEST MODE FOR CARRYING OUT THE INVENTION

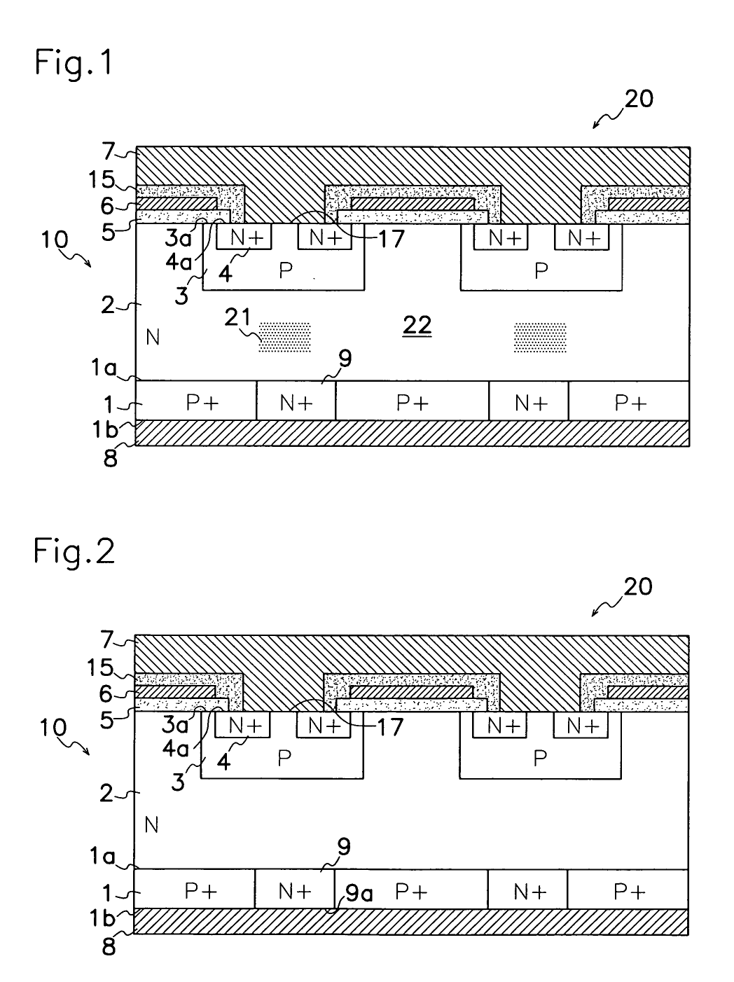

Embodiments of the insulated gate bipolar transistor according to the present invention will be described hereinafter in connection with FIGS. 1 to 7 of the drawings.

As shown in FIG. 1, IGBT 20 according to a first embodiment of the present invention comprises a semiconducting base plate or substrate 10 formed of for example silicon monocrystal which comprises a P+ type collector region 1, an N type or first base region 2 formed on one or upper surface of P+ collector region 1, P type or second base regions 3 formed adjacent to N type base region 2, and N+ type emitter regions 4 formed adjacent to P type base region 3. IGBT 20 further comprises gate electrodes 6 formed in spaced relation to P type base regions 3 via gate insulating film or insulator 5, an emitter electrode 7 formed on each upper or one main surface 3a, 4a of P type base region 3 and N+ type emitter region 4 in spaced relation to gate electrodes 6 through an insulating interlayer film 15, and a collector electrode 8 formed on bottom or the other main surface 1b of P+ type collector region 1 opposite to N type base region 2. Gate insulating films 5 are formed of for example silicon dioxide, and gate electrodes 6 made of for example polysilicon are formed on each upper surface of gate insulating films 5. Formed of for example silicon dioxide around gate electrode 6 is insulating interlayer film 15 which electrically insulates gate and emitter electrodes 6 and 7. Emitter and collector electrodes 7 and 8 are formed by for example a layered assembly of aluminum laminates or aluminum and nickel laminates.

Selectively formed in P+ type collector region 1 are a plurality of N+ type extended regions 9 of the same N type conductive type as that of N type base region 2 to configure a diode of PN junction to P type base region 3 together with N type base region 2. Each N+ type extended region 9 is formed in P+ collector region 1 into a circular section, belt shape or other plane shape in a plan view so that extended region 9 is connected to N type base region 2 and collector electrode 8 in P+ collector region 1. Shown N+ type extended region 9 is formed below each P type base region 3, however, it should not be limited to the shown arrangement. When a voltage is applied between emitter and collector electrodes 7 and 8 with the higher potential on emitter electrode 7, diode is turned on which is formed by P type base region 3, N type base region 2 and N+ type extended region 9, thus causing forward current to flow through the diode.

N type base region 2 comprises a recombination region 21 formed between P type base region 3 and collector electrode 8. Recombination region 21 is a recombination center formed by crystal defects in position of semiconducting substrate 10 to control lifetime of carrier in semiconducting substrate 10, and crystal detects are formed by irradiating electron beams, gamma rays, neutron rays or ion beams to semiconducting substrate 10. However, recombination region 21 should not reach between and beneath adjoining P type base regions 3, preferably between gate and collector electrodes 6 and 8. While radiation is irradiated beneath P type base regions 3 in N type base region 2, no radiation is irradiated between and beneath adjoining P type base regions 3 in N type base region 2. In this way, in this embodiment shown in FIG. 1, N type base region 2 comprises unirradiated regions 22 to which radiation is not irradiated between recombination regions 21.

Then, a voltage is applied between emitter and collector electrodes 7 and 8 with the higher potential on collector electrode 8 to turn off diode formed by P type base region 3, N type base region 2 and N+ type extended region 9 so that recombination region 21 acquires minority carriers accumulated around recombination region 21 in first base region 2 to rapidly annihilate minority carriers. Accordingly, the transistor can shorten turning-off time of diode and increase switching rate of diode. Also, during the on period of IGBT 20, forward current flows from P+ collector region 1 mainly through unirradiated regions 22 and channels in N type base region 2 to N+ type emitter region 4. Recombination region 21 does not reach between and beneath adjoining P type base regions 3 in N type base region 2, and forward current runs through mainly unirradated regions 22 in N type base region 2 to prevent a large power loss due to increase in forward voltage by recombination region 21.

More preferably, recombination region 21 may be formed between collector electrode 8 and emitter connection 17 for joining emitter electrode 7 and P type base region and N+ type emitter region 4. Diode current passes from emitter electrode 7 through emitter connection 17 to P type base region 3, and further through or around recombination region 21 formed between emitter connection 17 and collector electrode 8 to N+ type extended region 9 and collector electrode 8. In IGBT 20 according to the embodiment shown in FIG. 1, recombination region 21 is formed between emitter connection 17 and P+ type collector region 1 or N+ type extended region 9 in N type base region 2, and unirradiated regions 22 are formed in a wider area up to emitter connection 17 in a plan view. Accordingly, no crystal defect is formed in and around current path for forward current of IGBT 20 to reliably prevent increase in forward voltage along current path.

In manufacturing IGBT 20 shown in FIG. 1, an unirradiated IGBT 20 is prepared which comprises a plurality of N+ type extended regions 9 in P+type collector region 1 as shown in FIG. 2. Since manufacture of IGBT is known, explanation on manufacture is omitted. For example, N+ type extended region 9 is formed by firstly doping P type impurity into one surface of N− type base plate to form P+ type collector region 1, and then selectively diffusing N type impurity of elevated concentration into P+ type collector region 1. Thereafter, a collector electrode 8 is attached to bottom surfaces 1b, 9a of P+ type collector region 1 and N+ type extended region 9. By way of example, N+ type extended region 9 is formed into a cylindrical shape extending from contact surface of collector electrode 8 up to N type base region 2 by uniformly or unevenly doping and diffusing impurity over bottom surface of P+ type collector region 1. Impurity may be doped and diffused on stripe lines or other shapes in a plan view to form N+ type extended region 9. Otherwise, N+ type extended region 9 may be formed by a method disclosed in Japanese Patent Disclosure No. 9-191110 or other known techniques.

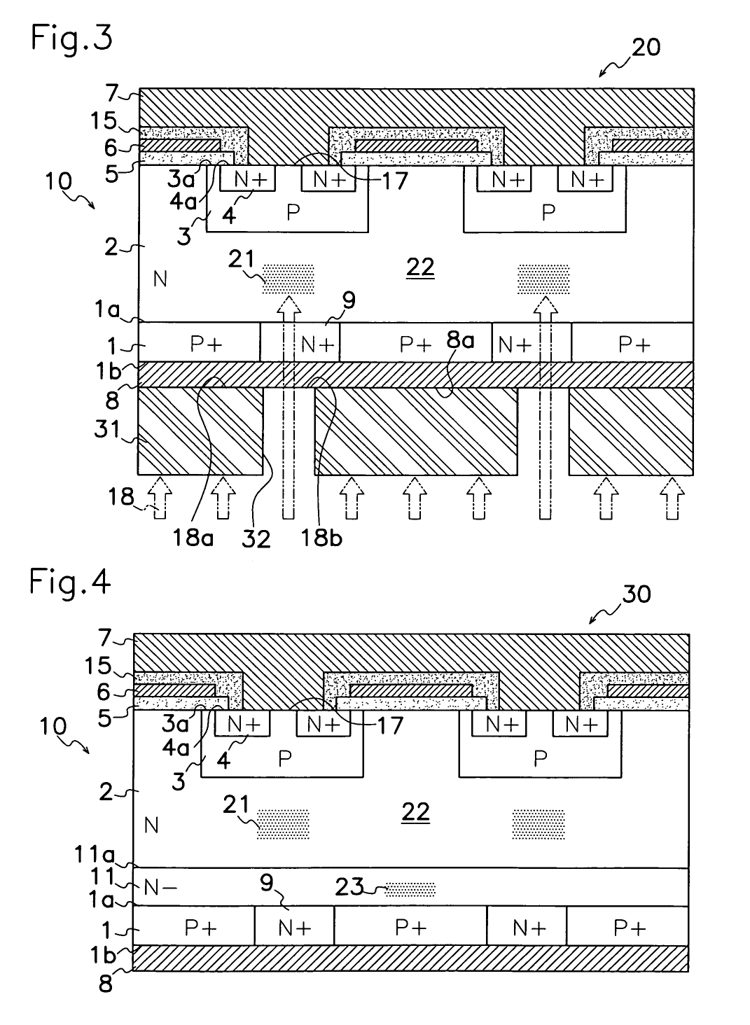

Subsequently, as shown in FIG. 3, attached to bottom surface 8a of collector electrode 8 is a mask 31 made of metal or other material for shielding radiation with openings 32, and for example, light ion beams 18 are irradiated toward mask 31. Light ion beams 18 are shielded or reduced by mask 31 which covers coated region 18a of IGBT 20 so that they do not reach semiconducting base plate, however, light ion beams 18 reach N type base region 2 of semiconducting base plate 10 on opened areas 18b through openings 32 to form crystal defects resulting in recombination region 21. Crystal defects may be formed in desired depth and in desired areas of semiconducting base plate 10 by appropriately adjusting intensity of light ion beam 18 or thickness of mask 31 or other conditions. In lieu of openings 32, notches not shown may be formed in mask 31 to selectively or partially thin thickness of mask 31. Crystal defects may be formed in N type base region 2 of semiconducting base plate 10 by irradiating light ion beams 18 through notches of mask 31 of low shielding effect. When mask 31 is removed from collector electrode 8, IGBT 20 shown in FIG. 1 is finished.

FIG. 4 illustrates another embodiment of the insulated gate bipolar transistor 30 according to the present invention. In IGBT 30 of this embodiment, semiconducting base plate 10 comprises a P+ type collector region 1, N− type buffer region 11 formed on upper surface la of P+ type collector region 1, an N type base region 2 formed on upper surface 11a of N− type buffer region 11, P type base regions 3 adjacent to N type base region 2, and N+ type emitter region 4 formed adjacent to P type base region 3. Like IGBT 20 shown in FIG. 20, IGBT 30 comprises gate insulating films 5, gate electrodes 6, insulating interlayer film 15, and emitter and collector electrodes 7 and 8. Collector electrode 8 is formed on bottom surface 1b of P+ type collector region 1 opposite to N− type buffer region 11. N− type buffer region 11 serves as a cathode region of diode, performing functions of optimizing amount of holes injected from P+ type collector region 1 to N type base region 2, and providing IGBT 20 with desirable conductivity modulation. Description is omitted about known IGBT having buffer region and conductivity modulation.

Like IGBT 20 shown in FIG. 20, IGBT 30 comprises a plurality of N+ extended regions 9 selectively formed in P+ collector region 1 to form a diode of PN junction in cooperation of N+ type extended regions 9, N type base region 2 and N− type buffer region 11. Also, N type base region 2 comprises recombination regions 21 formed between P type base region 3 and N− type buffer region 11, preferably between emitter connection 17 and N− type buffer region 11, and recombination regions 21 does not reach between and beneath adjoining P type base regions 3 in N type base region 2. This arrangement gives IGBT 30 shown in FIG. 4 similar effects as those in IGBT 20 shown in FIG. 1, however, IGBT 30 differs from IGBT 20 of FIG. 1 in that the former comprises a second recombination region 23 formed between gate and collector electrodes 6. As understood from FIG. 4, second recombination region 23 may be formed in N− type buffer region 11 by irradiating radiation beneath unirradiated region 22 of N type base region 2 and between adjoining P type base regions 3. No radiation is irradiated between and beneath adjoining P type base regions 3 in N type base region 2.

When IGBT 30 is turned on, forward current flows from P+ type collector region 1 through N− type buffer region 11, unirradiated region 22 and channels in N type base region 2 and N+ type emitter regions 4. Second recombination region 23 is a center of recombination for controlling lifetime of carrier in semiconducting substrate 10, and the center of recombination comprises crystal defects formed in desired areas of semiconducting substrate 10 by irradiating radiation on semiconducting substrate 10 with shorter irradiation distance than that for forming recombination region 21 from a side of collector electrode 8. When IGBT 30 is turned from on to off, second recombination region 23 acquires minority carrier accumulated around second recombination region 23 in N− type buffer region 11 to rapidly vanish minority carrier to effectively reduce tail current for improvement in switching property of IGBT 30.

In preparing IGBT 30 shown in FIG. 4, two semiconducting substrates 33 and 34 are formed both of silicon monocrystal. First semiconducting substrate 33 comprises an N type base region 2, P type base regions 3, N+ type emitter regions 4, an N− type buffer region 11, an upper surface 33a defined by N type base region 2 and P type base regions 3, and a bottom surface 33b defined by N− type buffer region 11. In first semiconducting substrate 33, N type base region 2 is formed over a main surface of N− type substrate by epitaxial growth, and then, different impurities are selectively doped in N type base region 2 in turn to form P type base region 3 and N+ emitter region 4. Second semiconducting substrate 34 comprises a P+ collector region 1, N+ type extended region 9, controller 35 of irradiation depth, an upper surface 34a formed with P+ collector region 1 and N+ extended region 9, and a bottom surface 34b formed with controller 35 of irradiation depth. Controller 35 comprises deep and shallow notches 36 and 37 formed in the thickness direction of second substrate 34. In second substrate 34 formed with controller 35, initially P type impurity is doped into one surface of second substrate 34 to form P+ collector region 1, and then N type impurity of thick concentration is selectively diffused on P+ collector region 1 to form N+ type extended region 9.

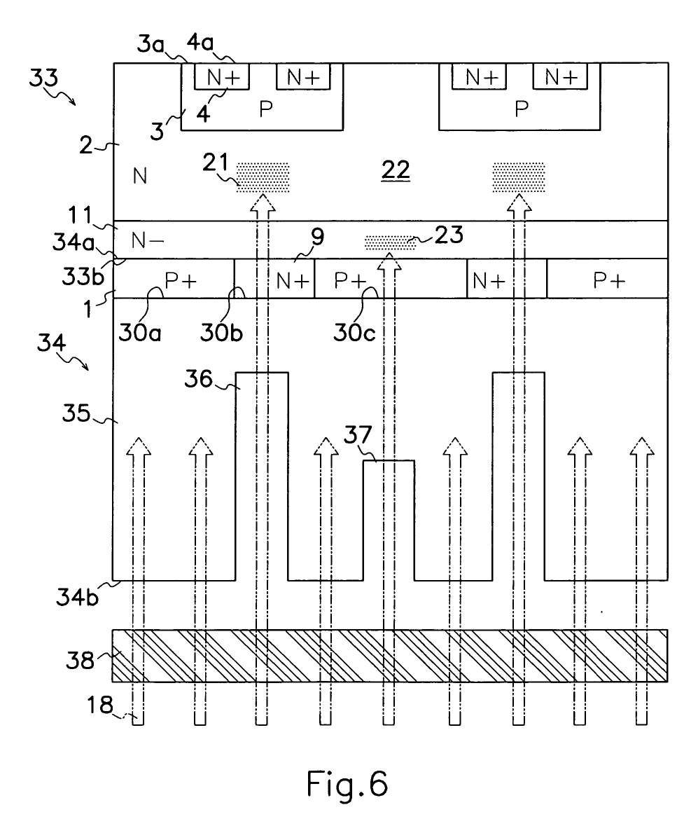

Next, bottom surface 33b of first substrate 33 is secured on upper surface 34a of second substrate 34. For example, bottom surface 33b of first substrate 33 and upper surface 34a of second substrate 34 may be polished into a mirror surface, and then contacted each other under heating for easy bonding, however, other joining techniques may be used. Thereafter, as illustrated in FIG. 6, a radiation attenuating mask 38 made of metal such as aluminum or other radiation shielding material is positioned under bottom surface 34b of second substrate 34 in spaced relation to controller 35 to irradiate for example light ion beams 18 toward radiation attenuating mask 38. Heavily shielded regions 30a of IGBT 30 guarded by controller 35 but without deep and shallow notches 36 and 37 are protected from or alleviated irradiation of light ion beams 18 by controller 35 so that light ion beams 18 cannot reach first substrate 33. On the contrary, light ion beams 18 penetrate and reach N type base region 2 of first substrate 33 through lightly shielded regions 30b of IGBT 30 covered by controller 35 with deep notches 36 to form crystal defects to become recombination regions 21. Also, in intermediately shielded regions 30c of IGBT 30 covered by controller 35 with shallow notches 37, light ion beams 18 reach N− type buffer region 11 of first substrate 33 to form crystal defects to become second recombination regions 23.

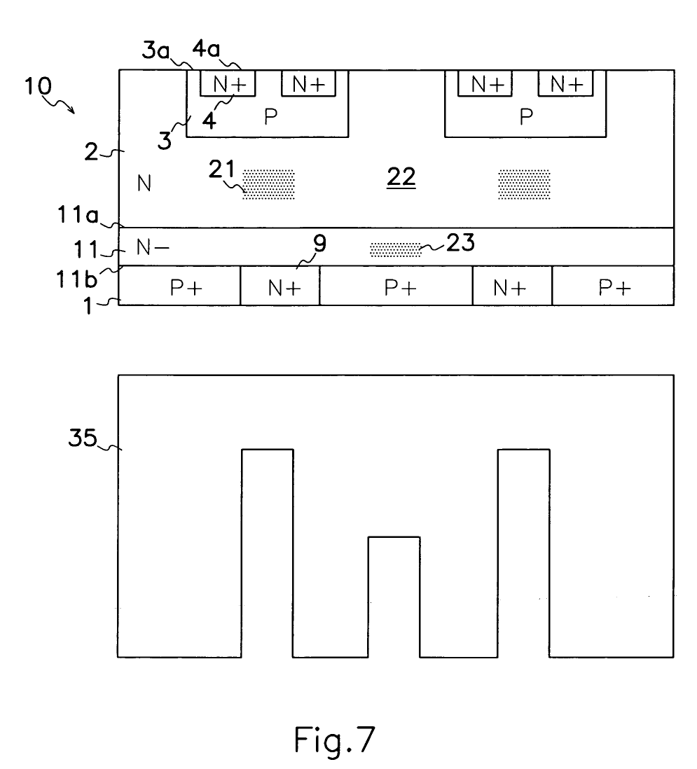

In this way, crystal defects may be formed in desired depth and in desired areas of first semiconducting substrate 33 by appropriately adjusting intensity of light ion beams 18, thickness of controller 35, depth of deep and shallow notches 36 and 37 or other conditions. Embodiment shown in FIG. 6 can particularly precisely control irradiation amount of radiation on to semiconducting substrate 10 because different thicknesses of silicon substrate can control irradiation distance or depth of radiation, unlike embodiment shown in FIGS. 2 and 3 employing mask 31 of different thickness portions. As shown in FIG. 7, controller 35 is removed from bonded first and second substrates 33 and 34, and then, gate insulating films 5, gate electrodes 6, insulating interlayer films 15, emitter and collector electrodes 7 and 8 are formed in turn to finish IGBT 30 of FIG. 4. Before irradiation of light ion beams 18, gate insulating films 5, gate electrodes 6, insulating interlayer films 15 and emitter electrode 7 may be formed in first semiconducting substrate 33 except collector electrode 8. On the other hand, radiation attenuating mask 38 may be omitted dependent on intensity of light ion beams 18 or thickness of controller 35.

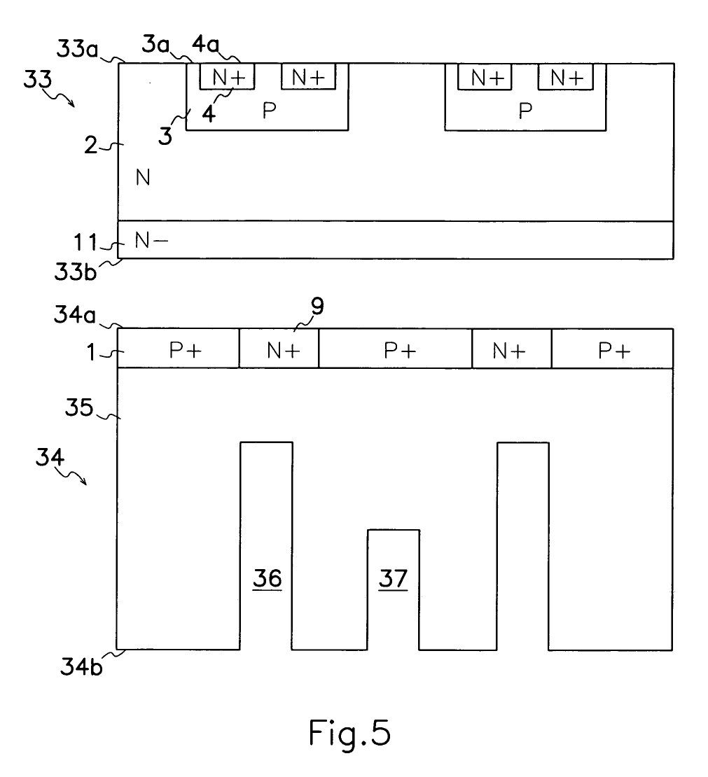

Embodiments of the invention can be carried out and modified in various ways without limitation to the foregoing embodiments shown in FIGS. 1 to 7. For example, IGBT 20 of FIG. 1 may be formed by techniques shown in FIGS. 5 to 7, and IGBT 30 of FIG. 4 may be formed by techniques shown in FIGS. 2 and 3.

The insulated gate bipolar transistors of the present invention are effectively and preferably applicable to various electric and electronic devices and hardware as power switching elements.

What is claimed are:

1. An insulated gate bipolar transistor comprising:
a semiconducting substrate which comprises:
a collector region of a first conductive type,
a first base region of a second conductive type different from said first conductive type and formed on one main surface of said collector region,
second base regions of the first conductive type each formed adjacent to said first base region, and
emitter regions of the second conductive type each formed adjacent to said corresponding second base region;
gate electrodes each formed in spaced relation to said corresponding second base region through an insulator;
an emitter electrode formed on one main surfaces of said second base region and emitter region; and
a collector electrode formed on the other main surface of said collector region opposite to said first base region;
wherein an extended region is selectively formed of the second conductive type in said collector region to form a diode in cooperation with said second base region, first base region and extended region,
said first base region comprises a recombination region formed between each of said second base regions and collector electrode, and
said recombination region does not reach between and beneath said adjoining second base regions.

2. An insulated gate bipolar transistor comprises a semiconducting substrate which comprises:
a collector region of a first conductive type,
a buffer region of a second conductive type different from said first conductive type and formed on one main surface of said collector region,
a first base region of a second conductive type different from said first conductive type and formed on one main surface of said collector region,
second base regions of the first conductive type each formed adjacent to said first base region, and
emitter regions of the second conductive type each formed adjacent to said corresponding second base region;
gate electrodes each formed in spaced relation to said corresponding second base region through an insulator;
an emitter electrode formed on one main surfaces of said second base region and emitter region; and
a collector electrode formed on the other main surface of said collector region opposite to said first base region;
wherein an extended region is selectively formed of the second conductive type in said collector region to form a diode in cooperation with said second base region, first base region and extended region,
said first base region comprises a recombination region formed between each of said second base regions and buffer region, and
said recombination region does not reach between and beneath said adjoining second base regions, and
said buffer region comprises a second recombination region formed between said gate electrodes and collector electrode.

3. The insulated gate bipolar transistor of claim 1 or 2, wherein said recombination region is formed between said collector electrode and emitter connection for joining said emitter electrode and second base regions or emitter regions.
